(19) United States
(12) Patent Application Publication
(10) Pub. No.: US 2013/0299989 A1
(43) Pub. Date: Nov. 14, 2013

(54) CHIP CONNECTION STRUCTURE AND METHOD OF FORMING

(71) Applicants: Charles L. Arvin, Poughkeepsie, NY (US); Timothy H. Daubenspeck, Colchester, VT (US); Jeffrey P. Gambino, Westford, VT (US); Christopher D. Muzzy, Burlington, VT (US); Wolfgang Sauter, Richmond, VT (US); Timothy D. Sullivan, Underhill, VT (US)

(72) Inventors: Charles L. Arvin, Poughkeepsie, NY (US); Timothy H. Daubenspeck, Colchester, VT (US); Jeffrey P. Gambino, Westford, VT (US); Christopher D. Muzzy, Burlington, VT (US); Wolfgang Sauter, Richmond, VT (US); Timothy D. Sullivan, Underhill, VT (US)

(73) Assignee: INTERNATIONAL BUSINESS MACHINES CORPORATION, Armonk, NY (US)

(21) Appl. No.: 13/468,750

(22) Filed: May 10, 2012

(51) Int. Cl. H01L 23/52; H01L 21/768

(52) U.S. Cl. 257/751; 438/618; 257/E23.141; 257/E21.575

(57) ABSTRACT

Chip connection structures and related methods of forming such structures are disclosed. In one case, an interconnect structure is disclosed, the structure including: a pillar connecting an integrated circuit chip and a substrate, the pillar including a barrier layer, a first copper layer over the barrier layer, and a first solder layer over the first copper layer.

### FIELD OF THE INVENTION

The subject matter disclosed herein relates to connections between integrated circuit chips. More specifically, the subject matter disclosed herein relates to chip connection structures and methods of forming such structures.

### BACKGROUND

As integrated circuit device technologies continue to shrink in size, the connections between chips (and substrates) have become finer. Conventionally, these finer connections between integrated circuit chips and a substrate can be formed using a copper pin. While copper pins can meet some of the size constraints in developing interconnects, copper pins can be rigid, causing undesirable joint stress in the interconnection.

### BRIEF SUMMARY

Chip connection structures and related methods of forming such structures are disclosed. In one case, an interconnect structure is disclosed, the structure including: a pillar connecting an integrated circuit chip and a substrate, the pillar including a barrier layer, a first copper layer over the barrier layer, and a first solder layer over the first copper layer.

A first aspect of the invention includes an interconnect structure, the structure including: a pillar connecting an integrated circuit chip and a substrate, the pillar including a barrier layer, a first copper layer over the barrier layer, and a first solder layer over the first copper layer.

A second aspect of the invention includes a method including: forming an interconnect structure between an integrated circuit chip and a substrate, the interconnect structure including at least one copper layer and at least one solder layer contacting the copper layer.

A third aspect of the invention includes a method of forming an interconnect structure, the method including: forming a mask over a chip body; plating a first copper layer on the chip body in an opening in the mask; forming a first solder layer over the first copper layer; forming a second copper layer over the first solder layer; and forming a second solder layer over the second copper layer, the second solder layer for connecting with a laminate.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 depicts an illustrative semiconductor structure according to various embodiments of the invention.

FIGS. 2a-2c and 3a-3c depict cross-sectional views of semiconductor structures undergoing processes according to various embodiments of the invention.

FIG. 4 depicts an illustrative semiconductor structure according to various alternative embodiments of the invention.

FIGS. 5a-5b depict cross-sectional views of a semiconductor structure undergoing processes according to various alternative embodiments of the invention.

FIGS. 6a-6b, 7a-7b and 8a-8b depict cross-sectional views of a semiconductor structure undergoing processes according to various alternative embodiments of the invention.

It is noted that the drawings of the invention are not necessarily to scale. The drawings are intended to depict only typical aspects of the invention, and therefore should not be considered as limiting the scope of the invention. In the drawings, like numbering represents like elements between the drawings.

### DETAILED DESCRIPTION

As noted herein, the subject matter disclosed relates to connections between integrated circuit chips. More specifically, the subject matter disclosed herein relates to chip connection structures and methods of forming such structures.

Various embodiments include an interconnect structure having: a pillar connecting an integrated circuit chip and a substrate. The pillar can include a barrier layer, a first copper layer over the barrier layer, and a first solder layer over the first copper layer. The pillar can be formed according to various methods, which are described with reference to embodiments herein.

The interspersed copper-and-solder pillar structures described according to the various embodiments of the invention can provide connection between a substrate and a chip, even in designs requiring finer dimensions. Additionally, in contrast to the conventional all-copper pillar, the copper-and-solder pillar structures disclosed according to the various embodiments can be more durable, and less prone to stress.

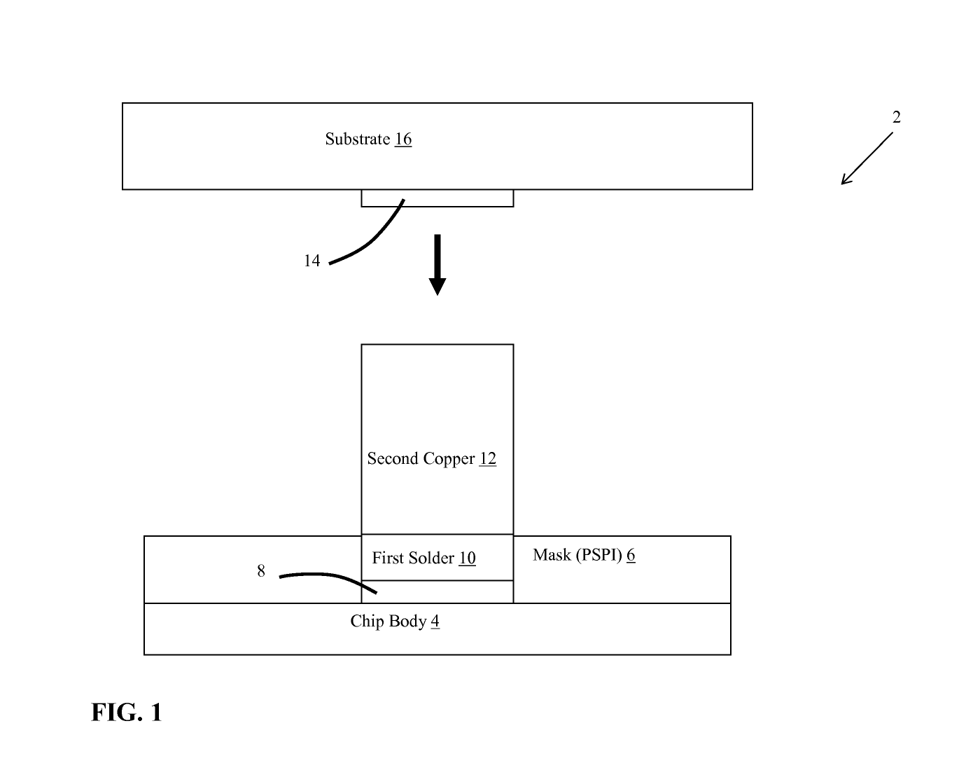

Turning to FIG. 1, a side cross-sectional view of an integrated circuit structure 2 is shown according to various embodiments of the invention. The integrated circuit structure 2 can include a chip body 4, and a mask layer 6 (e.g., a photosensitive polyimide, or PSPI layer, or a conventional photoresist layer) over the chip body 4. The mask layer 6 includes an opening which is filled by a first copper layer 8 and a first solder layer 10 over the first copper layer 8. In various embodiments, the mask layer 6 is formed over the chip body 4, and the first copper layer 8 is then formed by plating the copper in the opening within the mask layer 6. Following formation of the first copper layer 8 (e.g., via plating), a first solder layer 10 can then be formed over the first copper layer 8, e.g., via any conventional deposition technique described herein and/or known in the art.

For example, deposition techniques or the term “depositing” may be used to refer to any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

In any case, returning to FIG. 1, after forming of the first solder layer 10, a second copper layer 12 can be formed over the first solder layer 10, e.g., via plating the copper over the first solder layer 10. The second copper layer 12 can be formed as a copper pin structure, which has a thickness greater than a thickness of the first copper layer 8 and the first solder layer 10. In some embodiments, the second copper layer 12 is replaced with a plurality of alternating copper/solder layers, as is shown and described further herein.

Following forming of the second copper layer 12, a second solder layer 14 can be formed over the second copper layer 12 (e.g., as a separate solder layer overlying a substrate 16, as described herein). The second solder layer 14 can be formed in a similar fashion as the first solder layer 10, e.g., via one or more deposition techniques. The second solder layer 14 can be formed in order to contact a substrate 16, such as a laminate. In some cases, the second solder layer 14 is formed over the substrate 16 prior to joining with the second copper layer 12. That is, in these embodiments, the second solder layer 14 is formed on the substrate 16, which is then subsequently joined with the second copper layer 12, e.g., by reflowing the second solder layer 14 to bond the second solder layer 14 with the second copper layer 12.

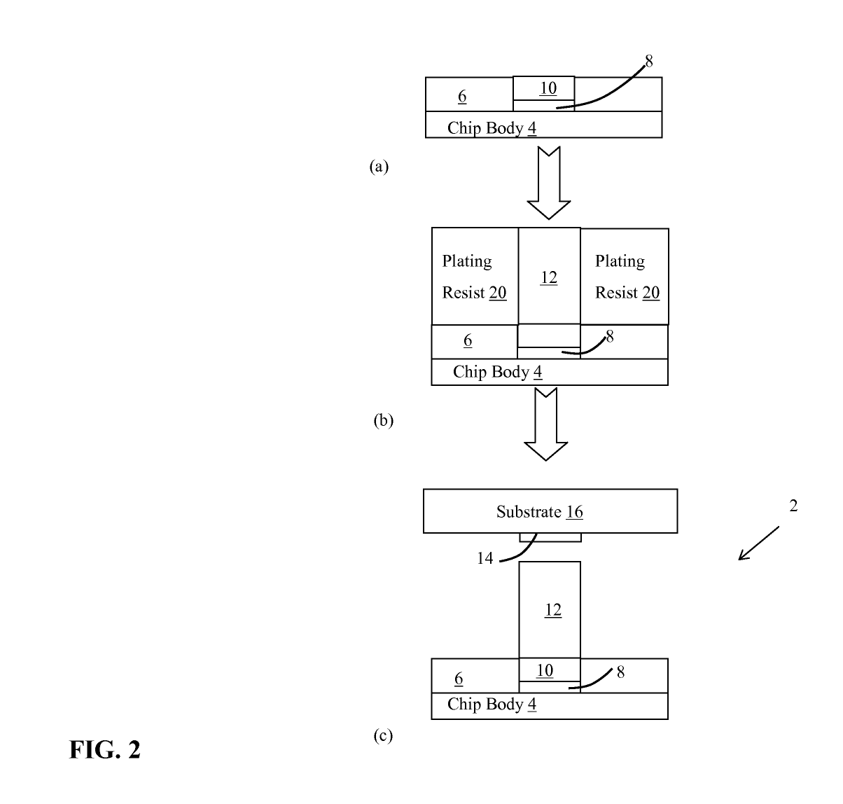

In various embodiments of the invention, the second copper layer 12 is formed by preliminarily forming a plating resist 20 over the mask 6 (e.g., the PSPI layer or photoresist layer), and then plating the second copper layer 12, e.g., to form a copper pin. This process is illustrated in the schematic depiction within FIGS. 2(a)-2(c). FIG. 2(a) shows a chip body 4 having a mask layer 6 and a first copper layer 8 over the mask layer 6. Overlying the first copper layer 8 is a first solder layer 10, which is formed in an opening within the mask layer 6. The first copper layer 8 can be formed by plating copper within a portion of the opening in the mask layer 6, and the first solder layer 10 can then be deposited over the first copper layer 8. In some cases, the mask layer 6 includes PSPI and is approximately 15 micrometers thick.

FIG. 2(b) shows a process of applying a plating resist 20 over the mask layer 6, e.g., by depositing conventional plating resist material on the mask layer 6. Following formation of the plating resist 20, a copper pin (or, second copper layer 12) can be plated within an opening in the plating resist. The second copper layer 12 is plated over the first solder layer.

FIG. 2(c) shows a process of stripping the plating resist 20, e.g., via conventional stripping techniques, and joining a second solder layer 14 (attached to a substrate 16) to the second copper layer to form an IC structure 2 described herein.

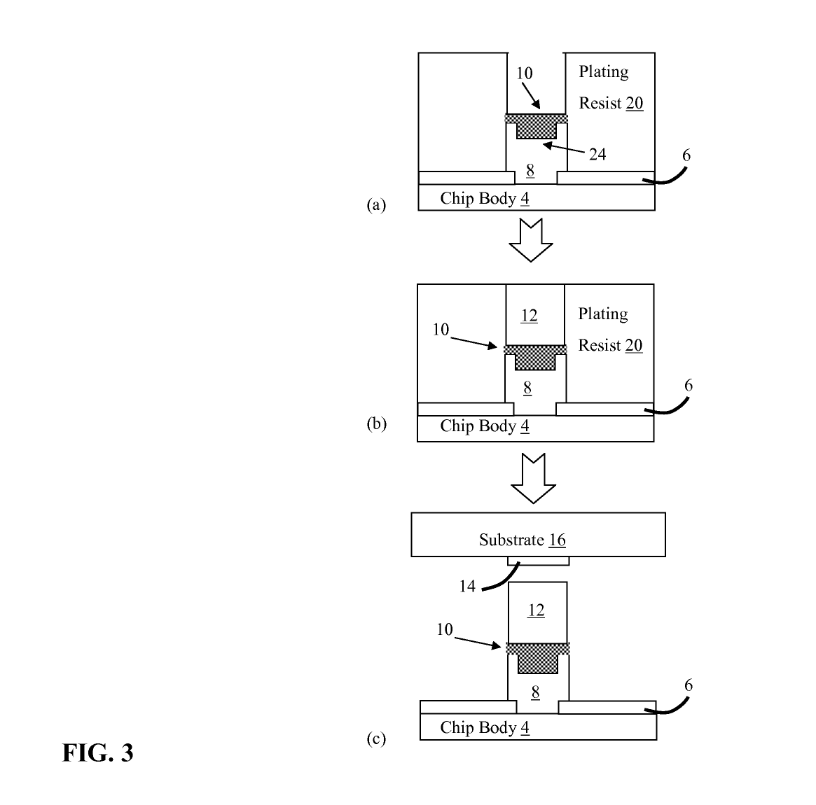

In some alternative embodiments, as shown in FIGS. 3(a)-(c), the first copper layer 8 is formed in the opening within the mask 6, as well as over a portion of the mask 6 to create a trough, or well 24 in an upper surface of the first copper layer 8. This well 24 can be used to capture a portion of the first solder layer 10, which can provide an improved connection between the first solder layer 10 and the first copper layer 8. Following formation of the first solder layer 10 in the well 24, the second copper layer 12 can be formed over the first solder layer 10 as described herein.

The resulting structure (and in particular, the second copper layer 12) can then be bonded to the second solder layer 14, as described with respect to FIGS. 2a-2c herein. It is understood that prior to bonding the second copper layer 12 with the second solder layer 14, the plating resist 20 can be stripped from over the mask 6. In some embodiments, as shown in FIG. 2(a), the mask 6 can be formed over the chip body 3, and the plating resist 20 can be formed mis-aligned with the mask 6, such that a portion of the mask 6 remains exposed after the forming of the plating resist 20. This creates a wider opening in the plating resist 20 than in the underlying mask 6, which helps to create the well 24 in the subsequently plated first copper layer 8.

In various embodiments of the invention, the first solder layer 10 and the second solder layer 14 are formed of different compositions, such that the solder layers have different solidification temperatures. In some cases, the first solder layer 10 includes a first solder alloy, having a first solidification temperature, and the second solder layer 14 includes a second solder alloy, having a second solidification temperature which is higher than the first solidification temperature.

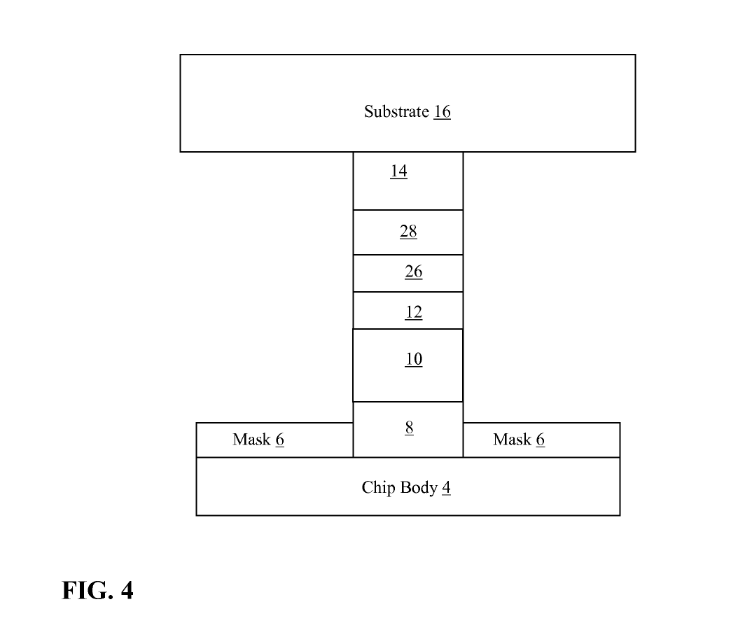

In other cases, as shown in FIG. 4, solder (including first solder layer 10 and second solder layer 14) may form approximately 50 percent of the total length of the pin between the chip body 4 and the substrate 16. In this case, an additional solder layer 26 and an additional copper layer 28 are formed over the first solder layer 12, respectively. In this case, the collective thickness of the solder and copper layers can be varied, and in particular embodiments, the thickness of the solder layers 10, 26 and 14 (collectively) can form approximately 50 percent of the total length of the pin between the chip body 4 and the substrate 16

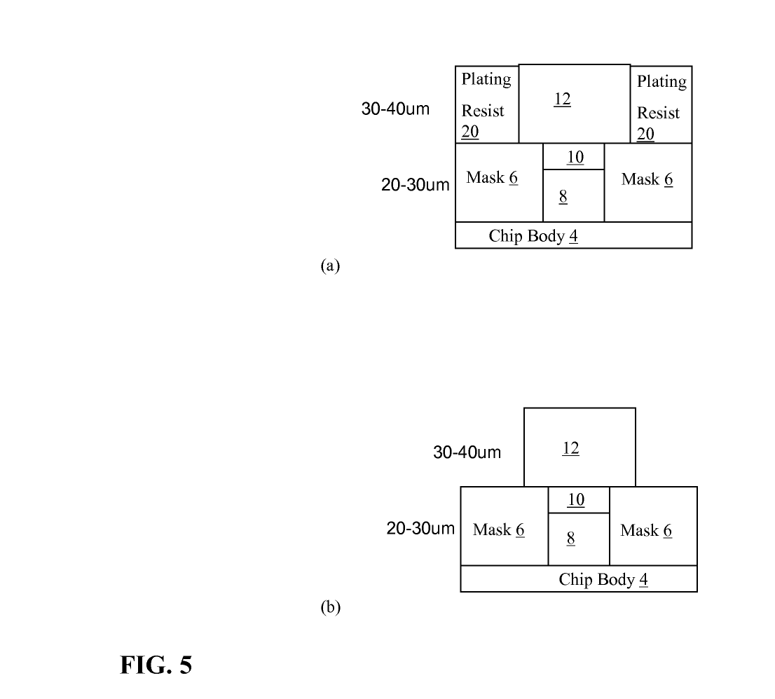

In yet other embodiments, as shown in FIGS. 5(a)-(b), the mask 6 is formed as a thicker layer, e.g., approximately 20-30 micrometers (um) thick, and the first copper layer 8 and first solder layer 10, respectively, are formed in the opening in the mask 6 (FIG. 5(a)). In this case, the second copper layer 12 is formed over the mask 6 and the first solder layer 10, e.g., using a plating resist 20 having an opening wider than the opening in the mask 6 (FIG. 5(a)). The second copper layer 12 can be plated over both the first solder layer 12 and the mask 6 according to various embodiments. In some cases, the plating resist 20 (and subsequently formed second copper layer 12, e.g., a copper pin) has a thickness, e.g., of approximately 30-40 micrometers. After formation of the second copper layer 12 within the opening in the plating resist 20, the plating resist can be removed, e.g., using conventional stripping techniques (FIG. 5(b)).

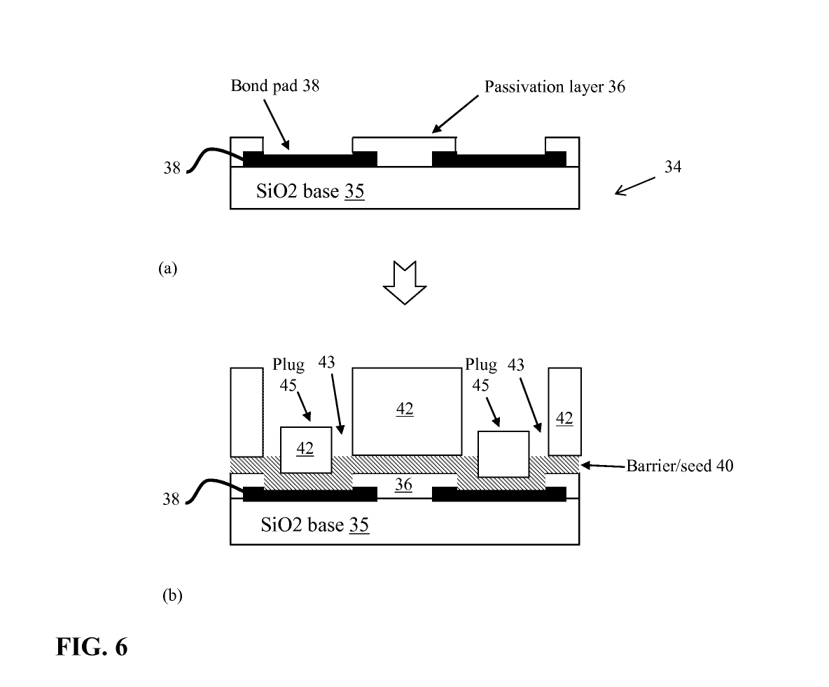

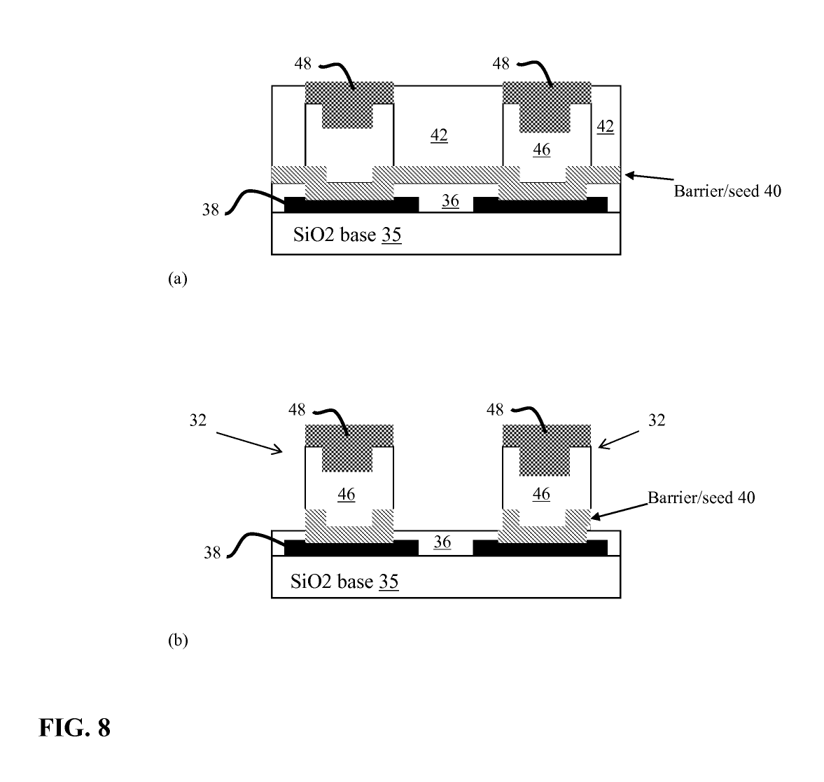

In some cases, as shown in FIGS. 6a-6b, 7a-7b and 8a-8b, one or more solder/copper pin structures 32 (FIG. 8) can be formed to connect a semiconductor structure 34 with a substrate (not shown). For example, in these cases, solder/copper pin structures 32 can be formed to connect a semiconductor structure (e.g., a complementary metal-oxide semiconductor, or CMOS structure) 34 to a substrate. The semiconductor structure 34 can include a silicon dioxide (SiO2) base layer 35, and a passivation layer 36 over the SiO2 base layer 35 In some cases, a process includes:

Forming a barrier/seed layer 40 over a bond pad 38 and passivation layer 36, e.g., via conventional deposition techniques (FIG. 6a-6b);

Forming a resist layer 42 over the barrier layer 40, the resist layer 42 including at least one plug which substantially fills a trench (or, well) in the barrier layer 40 (FIG. 6a-6b);

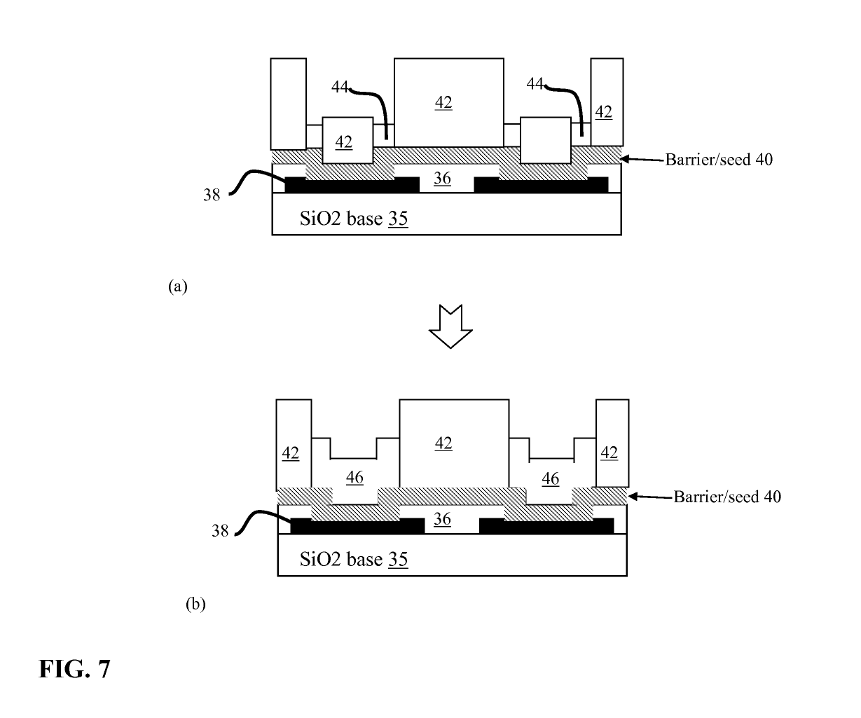

Forming a partial copper layer 44 (e.g., via partial plating, as shown in FIG. 7a) in openings 43 (FIG. 6a) within the resist layer 42 (FIG. 7a);

Removing the resist 42 (e.g., via conventional etching techniques) only in the openings (plugs) in the barrier layer 40 (FIG. 7b), leaving the remaining resist 42 outside of the openings (plugs) in the barrier layer 40;

Forming a remaining copper layer 46 over the partial copper layer 44 to fill the trench in the barrier layer 40 with copper layer 46 (FIG. 7b);

Forming a solder layer 48 (e.g., via plating) over the copper layer 46 within openings in the remaining resist 42, the solder layer 48 substantially filling a trench in the copper layer 46 (FIG. 8a); and

Removing the remaining resist 42, e.g., via conventional stripping techniques (FIG. 8b).

Following removal of the plating resist 20, the semiconductor structure 32 can be connected with a substrate, e.g., substrate 16 or another similar substrate shown and/or described herein.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

We claim:

1. An interconnect structure comprising:
a pillar connecting an integrated circuit chip and a substrate, the pillar including a barrier layer, a first copper layer over the barrier layer, and a first solder layer over the first copper layer.

2. The interconnect structure of claim 1, further comprising a bond pad over the first solder layer.

3. The interconnect structure of claim 1, wherein the bond pad contacts the substrate.

4. The interconnect structure of claim 3, wherein the barrier layer contacts the integrated circuit chip.

5. The interconnect structure of claim 1, wherein the barrier layer includes a trench, and a portion of the first copper layer fills the trench in the barrier layer.

6. The interconnect structure of claim 5, wherein the first copper layer includes a trench, and a portion of the first solder layer fills the trench in the first copper layer.

7. The interconnect structure of claim 1, further comprising a second copper layer over the first solder layer.

8. The interconnect structure of claim 7, further comprising a second solder layer over the second copper layer, wherein the second solder layer has a distinct solidification temperature from a solidification temperature of the first solder layer.

9. A method comprising:
forming an interconnect structure between an integrated circuit chip and a substrate, the interconnect structure including at least one copper layer and at least one solder layer contacting the copper layer.

10. The method of claim 9, wherein the forming of the interconnect structure includes forming the at least one copper layer to include a well.

11. The method of claim 10, wherein the forming of the interconnect structure includes forming the at least one solder layer to fill the well in the at least one copper layer.

12. The method of claim 9, wherein the substrate includes a laminate.

13. The method of claim 12, wherein the at least one solder layer is formed to contact the laminate.

14. The method of claim 9, wherein the at least one copper layer includes two distinct copper layers separated by the at least one solder layer.

15. A method of forming an interconnect structure, the method comprising:
forming a mask over a chip body;
plating a first copper layer on the chip body in an opening in the mask;
forming a first solder layer over the first copper layer;
forming a second copper layer over the first solder layer; and
forming a second solder layer over the second copper layer, the second solder layer for connecting with a laminate.

16. The method of claim 15, wherein the forming of the mask over the chip body includes forming one of a photosensitive polyimide mask or a photoresist mask.

17. The method of claim 15, wherein the second copper layer includes a copper pin.

18. The method of claim 17, wherein the forming of the second copper layer includes forming a plating resist layer over the mask, and plating the second copper layer in an the opening in the mask.

19. The method of claim 15, wherein the forming of the first copper layer includes forming a plating resist over the mask, and plating the first copper layer in the opening in the mask and an opening in the plating resist.

20. The method of claim 19, wherein the opening in the plating resist is larger than the opening in the mask.
